(19) United States
(12) Patent Application Publication
(10) Pub. No.: US 2019/0013428 A1
(43) Pub. Date: Jan. 10, 2019

(54) CONNECTION CELLS FOR PHOTOVOLTAIC MODULES

(71) Applicant: Corner Star Limited, Kowloon (HK)

(72) Inventors: Gang Shi, Carbondale, IL (US); Bhavananda Reddy Nadimpally, Glasgow, KY (US); Lee William Ferry, St. Charles, MO (US); Jeanette Lee Bearden, Winfield, MO (US); Aditya Janardan Deshpande, Chesterfield, MO (US); Vikrant Ashok Chaudhari, Cengaluru (IN)

(73) Assignee: Corner Star Limited, Kowloon (HK)

(21) Appl. No.: 16/067,433

(22) PCT Filed: Feb. 17, 2017
(86) PCT No.: PCT/US17/18369

§ 371 Date: Jun. 29, 2018

(30) Foreign Application Priority Data
Feb. 19, 2016 (IN) 201611005824

(51) Int. Cl. H01L 31/05; H01L 31/0224; H01L 31/02; H02S 40/36; H01L 31/044; H01L 31/048

(52) U.S. Cl. CPC H01L 31/0508; H01L 31/022441; H01L 31/048; H02S 40/36; H01L 31/044; H01L 31/0201

(57) ABSTRACT

A shingled photovoltaic (PV) cell module is provided. The PV cell module includes a first PV cell string and a first connection cell. The first PV cell string includes a plurality of shingled PV cell segments. Each PV cell segment includes a front electrode and an opposing rear electrode electrically coupled to the front electrode. The front electrode of the PV cell segment is aligned and coupled with the rear electrode of an adjacent PV cell segment of the plurality of PV cell segments to electrically couple the plurality of PV cell segments in series. The first connection cell includes a ribbon electrode and a first electrode electrically coupled to the ribbon electrode and a first PV cell segment. The ribbon electrode is coupled to a conductor adjacent to the first PV cell string to transfer a power output of the PV cell segments.

### CROSS REFERENCE TO RELATED APPLICATION

This application claims the benefit of priority to Indian Patent Application number 201611005824, which was filed 19 Feb. 2016, the disclosure of which is hereby incorporated by reference as if set forth in its entirety.

### FIELD

This disclosure relates generally to photovoltaic (PV) modules and, more specifically, connection cells and methods for assembling strings of shingled PV cells with the connection cells for use in PV modules.

### BACKGROUND

Some known photovoltaic (PV) strings are constructed by shingling cells using PV cell segments produced from full size PV cells. Constructing PV modules using strings of shingled cells reduces electrical and optical losses compared to the conventional solar modules in which full size cells are soldered using copper ribbons on silver busbars. FIGS. 1A and 1B are bottom views of portions of two typical PV modules 10, 15. PV modules 10, 15 include four PV cell strings 20, each of which includes a plurality of PV cell segments 25 that are electrically coupled to each other. The PV cell segments 25 are portions of PV cells that are split apart and shingled.

Each PV cell segment 25 has a front electrode (not shown) and a back electrode 26 with two terminals. The PV cell segments produce an electrical power output that is coupled between the front and back electrodes. Each pair of adjacent PV cell segments 25 is electrically coupled together with the front electrode of one segment connected to the back electrode of the adjacent segment. In some known systems, an electrically conductive adhesive (ECA) is disposed between the electrodes of adjacent segments. In some systems, a solder paste is used in place of the ECA. As used herein, the term “ECA” includes electrically conductive adhesive, solder, solder paste, conductive tapes, and any other material for use electrically and mechanically connecting electrodes PV cell segments. The power outputs of the PV cell segments 25 are collected through the PV cell string 20.

To retrieve the power output from each PV cell string 20, electrically conductive ribbons and/or busbars 30 extend in a relatively complicated arrangement through PV modules 10, 15. The conductive ribbon 30 is fabricated from a conductive material, such as copper, silver, and aluminum. The ribbon 30 is typically disposed on the bottom or back side (i.e., the side that does not face the sun) of the PV modules 10, 15. The ribbon 30 includes a plurality of tabs 34, an internal ribbon 36, and bypass diodes 38. The tabs 34 are made from a similar material as the ribbon 30 and extend between the terminals of the electrodes and the ribbon 30. For example, the tabs 34 may be used to couple a front electrode of a PV cell segment 25 to the ribbon 30. The bypass diodes 38 are configured to enable electrical current to bypass inactive or reduced performance PV cell segments 25. For example, the bypass diodes 38 may divert current away from a shaded PV cell segment 425 or a damaged PV cell segment 425.

The PV modules 10, 15 include gaps 40, 45, respectively between the PV cell strings 20. The internal ribbon 36 is disposed within the gap 40 with the tabs extending from the terminals of the adjacent electrodes. The internal ribbon 36 may be used to electrically couple multiple PV cell strings together and to couple other components to an intermediate power output of the PV modules 10, 15, such as a junction box, a load, or a bypass diode (e.g., bypass diodes 38). The gaps 40, 45 increase the size of the PV modules 10, 15 and leave spaces between the PV cell segments 25 that may be discontinuous and/or visually unappealing from the front of the PV modules 10, 15. The PV module 15 reduces the size of the gap 45 by moving the internal ribbon 36 below one of the PV cell segments 25, however the tabs 34 may cause the PV module 15 to be difficult to fabricate.

In addition, the tabs 34 may be susceptible to damage that may reduce the efficiency (power efficiency, cost efficiency, space efficiency, etc.) of the PV modules 10, 15. For example, the tabs 34 increase the number of soldering points (i.e., joints coupled together via solder or another conductive adhesive) of the PV modules 10, 15, which may increase the cost of the PV modules 10, 15. Moreover, the tabs 34 that extend to the front side of the PV modules 10, 15 may cause the PV modules 10, 15 to appear discontinuous and/or visually unappealing.

This Background section is intended to introduce the reader to various aspects of the art that may be related to various aspects of the present disclosure, which are described and/or claimed below. This discussion is believed to be helpful in providing the reader with background information to facilitate better understanding of the various aspects of the present disclosure. Accordingly, it should be understood that these statements are to be read in this light, and not as admissions of prior art.

### BRIEF DESCRIPTION

In one aspect, a shingled photovoltaic (PV) cell module is provided. The PV cell module includes a first PV cell string and a first connection cell. The first PV cell string includes a plurality of shingled PV cell segments. Each PV cell segment includes a front electrode and an opposing rear electrode electrically coupled to the front electrode. The front electrode of the PV cell segment is aligned and coupled with the rear electrode of an adjacent PV cell segment of the plurality of PV cell segments to electrically couple the plurality of PV cell segments in series. The first connection cell includes a ribbon electrode and a first electrode electrically coupled to the ribbon electrode and a first PV cell segment. The ribbon electrode is coupled to a conductor adjacent to the first PV cell string to transfer a power output of the PV cell segments.

In another aspect, a connection cell for coupling a shingled PV cell string including a plurality of PV cell segments to a conductor is provided. The connection cell including a first electrode and a ribbon electrode electrically coupled to the first electrode. The first electrode is electrically coupled to a first PV cell segment of the PV cell segments. The ribbon electrode is coupled to a conductor adjacent to the PV cell string to transfer a power output of the PV cell segments.

### BRIEF DESCRIPTION OF THE DRAWINGS

FIG. 1A is a bottom view of a prior art PV module with shingled photovoltaic (PV) cell segments.

FIG. 1B is a bottom view of another prior art PV module with shingled PV cell segments.

FIG. 2 is a perspective view of an example PV module.

FIG. 3 is a cross-sectional view of the PV module shown in FIG. 2.

FIG. 4 is a top plan view of a PV cell for production of PV cell segments.

FIG. 5 is a top plan view of the PV cell shown in FIG. 4 after singulation.

FIG. 6 is an illustration of the process for assembling PV cell segments into a shingled PV cell string.

FIG. 7 is a bottom view of an example PV module with shingled PV cells and connection cells.

FIG. 8 is an example cross-sectional side view of a first end of the PV module shown in FIG. 7 including a first connection cell.

FIG. 9 is an example cross-sectional side view of a middle portion of the PV module shown in FIG. 7 including the first connection cell.

FIG. 10 is an example cross-sectional side view of a second end of the PV module shown in FIG. 7 including a second connection cell.

FIG. 11 is a bottom view of the example first connector cell shown in FIGS. 8 and 9.

FIG. 12 is a bottom view of the example second connector cell shown in FIG. 10.

FIG. 13 is a bottom view of another example PV module with shingled PV cells and connection cells.

FIG. 14 is a bottom view of another example PV module with shingled PV cells and connection cells.

Corresponding reference characters indicate corresponding parts throughout the several views of the drawings.

### DETAILED DESCRIPTION

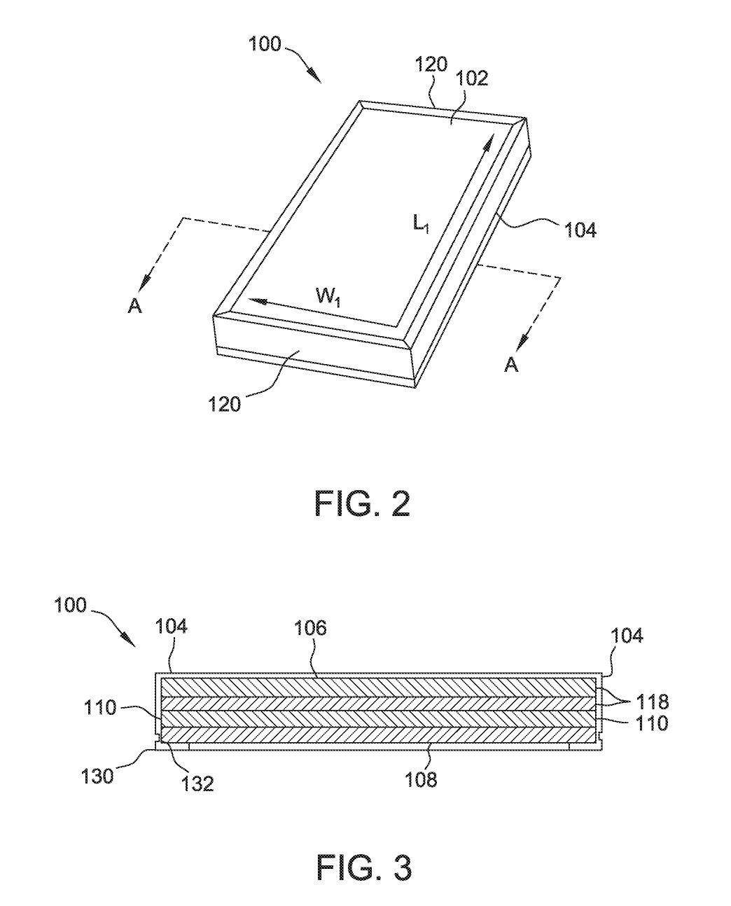

Referring initially to FIGS. 2 and 3, one embodiment of a photovoltaic (PV) module is indicated generally at 100. A perspective view of the PV module 100 is shown in FIG. 2. FIG. 3 is a cross-sectional view of the PV module 100 taken at line A-A as shown in FIG. 2. PV module 100 includes a laminate 102 and a frame 104 circumscribing the laminate 102.

The laminate 102 includes a top surface 106 (also referred to as a sun receiving side) and a bottom surface 108 (shown in FIG. 3). Edges 110 extend between the top surface 106 and the bottom surface 108. In this embodiment, the laminate 102 is rectangular shaped. In other embodiments, the laminate 102 may have any suitable shape. The laminate 102 has a width W₁ and a length L₁.

As shown in FIG. 3, the laminate 102 has a laminate structure that includes several layers 118. The layers 118 may include, for example, glass layers, encapsulant, non-reflective layers, electrical connection layers, n-type silicon layers, p-type silicon layers, and/or backing layers. One or more of the layers 118 may also include strings of PV cells (not shown in FIGS. 2 and 3). In the example embodiment, the laminate 102 includes (from top surface 106 to bottom surface 108) a glass layer (also referred to as a front layer), a front side encapsulant layer, a layer of PV cell strings (which also includes encapsulant), a back side encapsulant layer, and a backsheet or glass layer (also referred to as a rear layer). In other embodiments, the laminate 102 may have more or fewer, including one, layers 118, may have different layers 118, and/or may have different types of layers 118. Moreover, the front layer and the rear layer may be materials other than glass, such as a plastic, another laminate, a film, and the like.

Each string of PV cells within laminate 102 includes multiple PV cells connected in series. In the example embodiment, each string of PV cells includes multiple PV cell segments connected in series. The strings of PV cells within laminate 102 are electrically connected to each other in series, parallel, or a combination of series and parallel connections to produce a desired output voltage and current. In embodiments with multiple PV cell strings, the PV cell strings are typically coupled to each other within a junction box. Alternatively, the PV cell strings may be coupled together within the laminate 102.

As shown in FIG. 3, the frame 104 circumscribes laminate 102. The frame 104 is coupled to the laminate 102, as best shown in FIG. 2. The frame 104 includes four frame members 120. The frame 104 assists in protecting the edges 110 of the laminate 102 and provides additional rigidity to the PV module 100. The example frame 104 includes an outer surface 130 spaced apart from the laminate 102 and an inner surface 132 adjacent the laminate 102. The outer surface 130 is spaced apart from and substantially parallel to the inner surface 132. In the example embodiment, the frame 104 is made of aluminum. More particularly, in some embodiments the frame 104 is made of 6000 series anodized aluminum. In other embodiments, the frame 104 may be made of any other suitable material providing sufficient rigidity including, for example, rolled or stamped stainless steel, plastic, or carbon fiber.

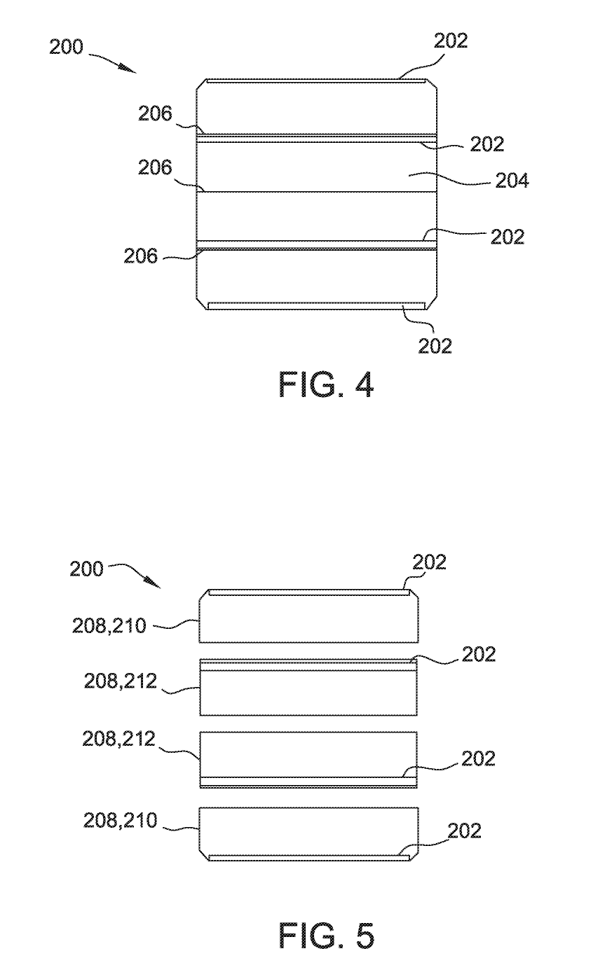

FIG. 4 is a top plan view of an example PV cell 200 for production of PV cell segments. The PV cell 200 includes busbars 202 disposed on the top surface of a silicon substrate 204. The busbars 202 are sometimes referred to as front electrodes. The rear surface (not shown) of the silicon substrate includes one or more rear electrodes. The silicon substrate 204 may be a monocrystalline silicon substrate or a polycrystalline substrate. The PV cell 200 can include fingers (not shown) disposed on the silicon substrate 204 substantially perpendicular to the busbars 202. In an embodiment, the PV cell 200 has three cut lines 206 at which PV cell 200 will be separated into PV cell segments. The fingers disposed on substrate 204 do not extend over the cut lines 206. Alternatively, the fingers extend over one or more of the cut lines 206. With four busbars 202 and three cut lines 206, the illustrated PV cell 200 is configured for singulation into four PV cell segments. Alternatively, the PV cell 200 may be configured for singulation into more or fewer PV cell segments. For example, in various embodiments, the PV cell 200 is configured for singulation into no less than two PV cell segments, no less than three PV cell segments, or no less than six PV cell segments.

FIG. 5 is a top plan view of the PV cell 200 after singulation. The PV cell 200 has been separated at the cut lines 206 into four PV cell segments 208 (sometimes referred to as cells). The PV cell 200 may be separated into PV cell segments 208 by cutting at the cut lines 206, such as with a saw or a laser cutter, by ablating or etching at the cut lines and snapping the substrate 204 at the etching, or by any other suitable method dividing the substrate 204 (shown in FIG. 4). Because the silicon substrate 204 of the PV cell 200 has a pseudo-square shape, the two PV cell segments 208 on the outside edges of the PV cell 200 are chamfered segments 210. The PV cell segments 208 singulated from the interior portion of the PV cell 200 are rectangular segments 212.

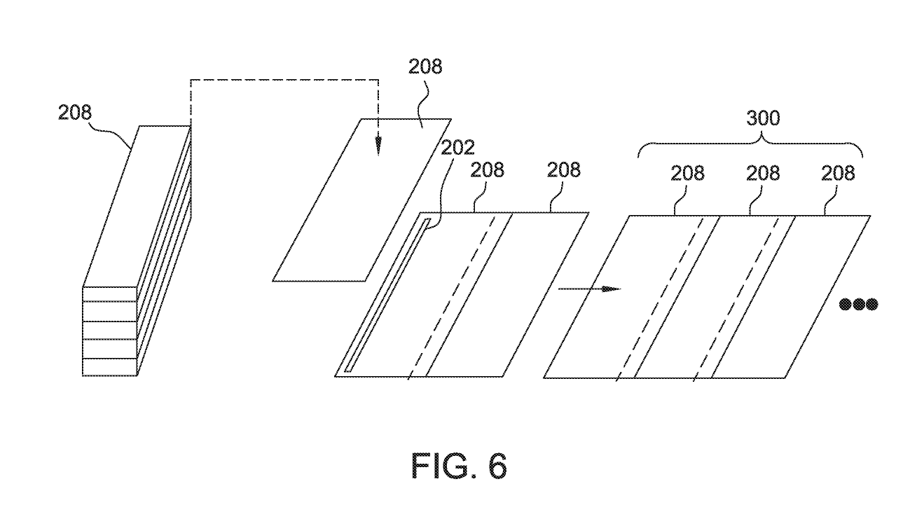

FIG. 6 is an illustration of the process for assembling PV cell segments 208 into a shingled PV cell string 300. The PV cell segments 208 are overlapped with the front electrode (i.e., busbar 202) of the lower PV cell segment 208 directly contacting the rear electrode (not shown in FIG. 6) of PV cell segment 208 positioned above it. As used herein, direct contact, direct connection, directly contacting, directly connected, and the like describe physical contact between two components (such as electrodes) without a foreign material between the components at the contact point. No electrically conductive adhesive (ECA) or foreign material is used to mechanically and/or electrically connect the PV cell segments 208 to each other. Alternatively, the PV cell string may use ECA or another coupling material to couple the PV cell segments 208 together. The overlap between adjacent PV cell segments may be between 0.001 mm and 156 mm. Although PV cell segments are described above, it is to be understood that whole PV cells may be assembled into a shingled PV cell string following similar steps to the PV cell segments 208.

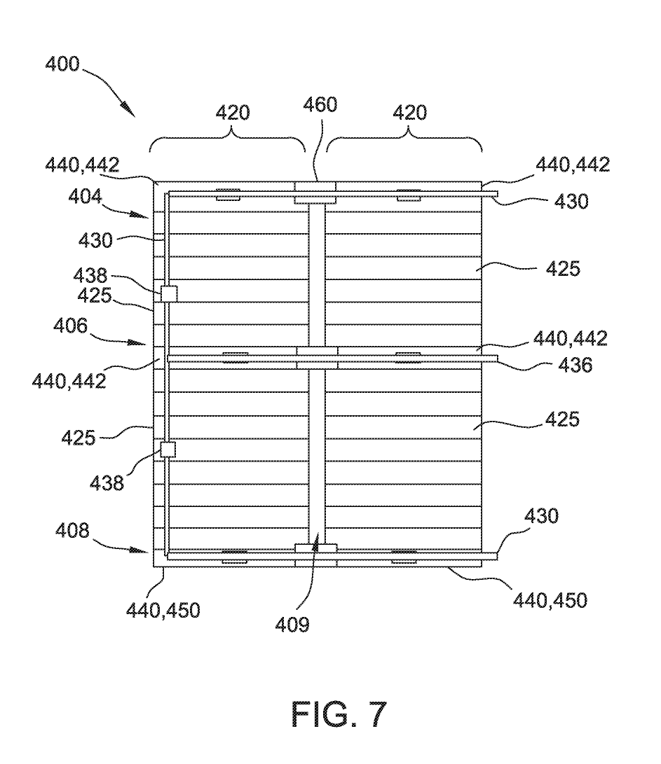

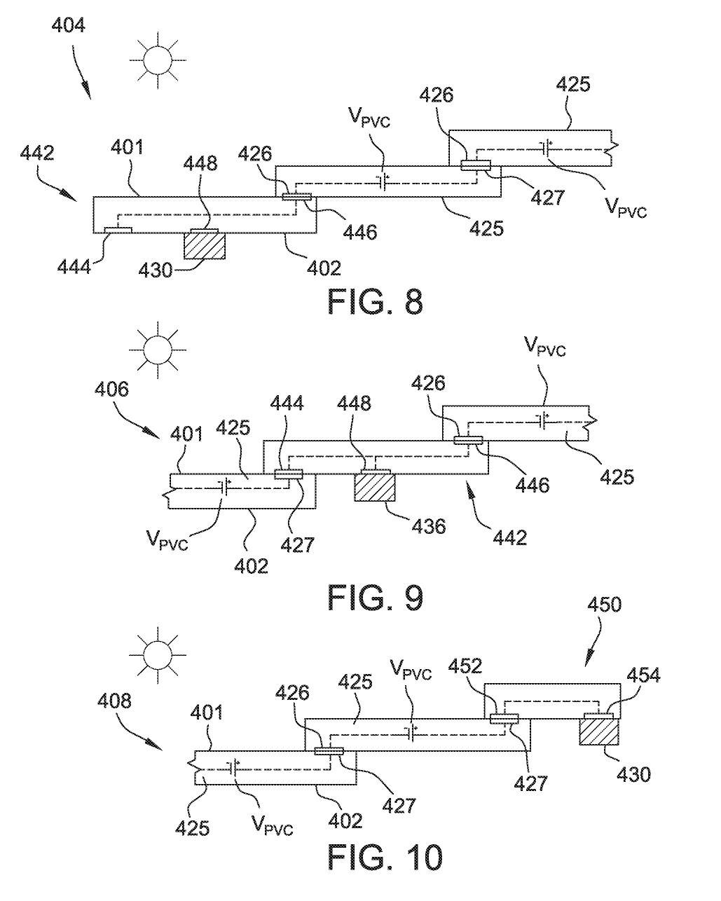

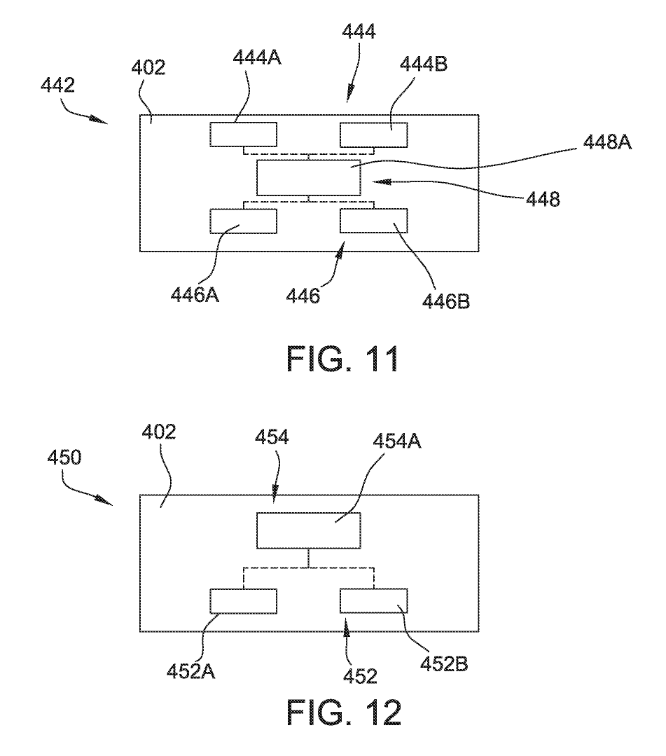

FIGS. 7-12 are various views of an example PV module 400 in accordance with the present disclosure. More specifically, FIG. 7 is a bottom view of the PV module 400 and FIGS. 8-10 are example cross-sectional side views of a first end 404, a middle portion 406, and a second end 408 of the PV module 400 including connection cells as described herein. FIGS. 11 and 12 are bottom views of connection cells as described herein.

With reference to FIG. 7, the PV module 400 includes two PV cell strings 420 with a plurality of shingled PV cell segments 425. That is, the PV cell segments 425 partially overlap each adjacent segment 425 to electrically couple the PV cell segments together. The PV cell strings 420 include the first end 404, middle portion 406, and bottom end 408. The first and second ends 404, 408 are coupled to one or the connection cells 440. The middle portion 406 includes one of the connector cells 440 within the PV cell string 420. The middle portion 406 may be any portion of the PV cell string 420 between the first and second ends 404, 408. The PV cell strings 420 are separated by a gap 409 that extends the length of the PV module 400. The PV module 400 further includes a conductor or conductive ribbon 430, connection cells 440, and patches 460. The ribbon 430 includes an internal ribbon 436 extending through the middle portion 406 of the PV cell strings 420. The ribbon 430 extends along the PV cell strings 420 and over the gap 409 to accumulate a power output from the PV cell strings 420. The ribbon 430 further includes bypass diodes 438 configured to divert electrical current from shaded or damaged PV cell segments 425 to facilitate reduced power losses for the PV module 400.

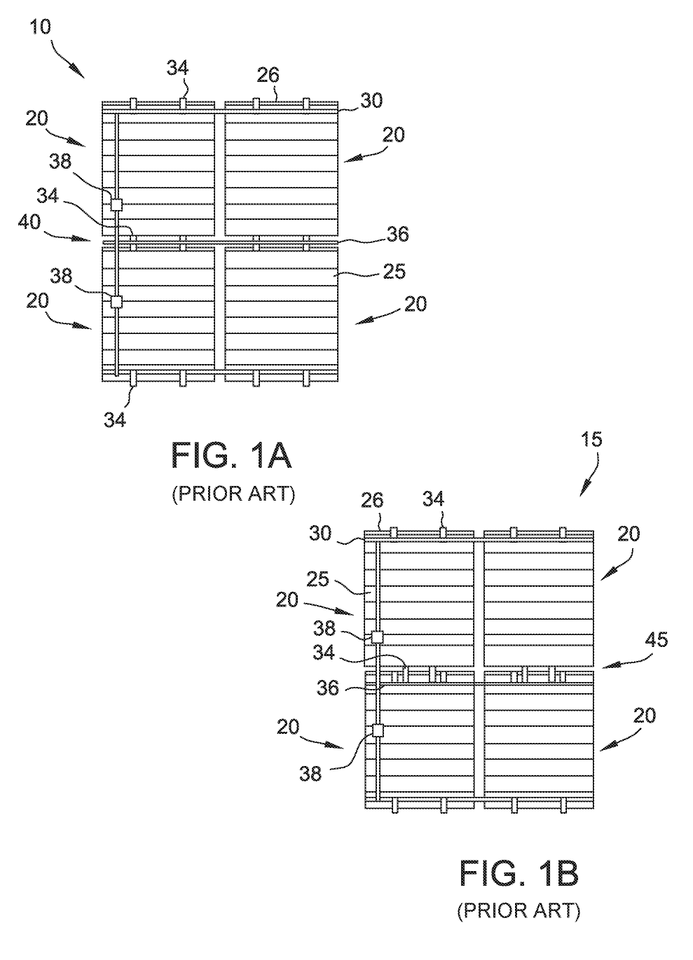

The connection cells 440 are fabricated from a material similar to the PV cell segments 425, such as silicon. In other embodiments, the connection cells 440 may be a different material, such as ceramics or plastics with a conductive layer. The connection cells 440 are positioned through the PV cell strings 420 to replace the tabs 34 and the gaps 40, 45 of the PV modules 10, 15 shown in FIGS. 1A and 1B. In the example embodiment, the connection cells 440 include two types of connection cells, a first type connection cell 442 and a second type connection cell 450 as described herein. Alternatively, the connection cells 440 may include a different number of types, such as one or three types of connections cells.

With reference now to FIGS. 8 and 9, first type connection cells 442 are coupled to shingled PV cell segments 425 at the first end 404 and the middle portion 406, respectively. In the example embodiment, the PV cell segments 425 and the first type connection cells 442 include a first (front/sun-facing) surface 401 and a second (rear) surface 402. Each PV cell segment 425 includes a rear electrode 426, a front electrode 427, and a power output indicated generally as V. As the PV cell segments 425 are shingled, each rear electrode 426 and front electrode 427 of two adjacent PV cell segments 425 are aligned and directly electrically coupled together. In some embodiments, a conductive material, such as solder or ECA, may be used between the electrodes 426 and 427 to couple the adjacent segments 425 together.

The first type connection cell 442 includes rear electrodes 444, front electrodes 446, and a ribbon electrode 448 that are electrically coupled together. In some embodiments, the first type connection cell 442 has PV characteristics. In other embodiments, the first type connection cell 442 is inactive (i.e., does not have PV characteristics). The first type connection cell 442 is configured to be connected to one or more PV cells and the ribbon 430 to facilitate coupling to the ribbon 430 at the rear surface 402 without tabs. Although the electrodes 426, 427, and 444 are shown disposed level with the surface of the PV cell segments 425 and the first type connection cell 442, it is to be understood that the electrodes 426, 427, and 444 may be in a different configuration, such as outwardly extending from the surface of the PV cell segment 425 and/or the first type connection cell 442. With reference to FIG. 11, the first type connection cell 442 includes a pair of spaced apart terminals for each electrode 444, 446 (444A, 444B and 446A, 446B, respectively). The electrodes 444, 446 are electrically coupled to the ribbon electrode 448, which has a single terminal 448A. The single terminal 448A enables the ribbon 430 to be electrically coupled to first type connection cell 442, and indirectly to the PV cell segment 425, without requiring multiple soldering points. In other embodiments, the electrodes 444, 446, 448 may include a different number of terminals. Additionally or alternatively, the first connection cell 442 may include a different configuration of electrodes and terminals.

With reference now to FIG. 8, the first type connection cell 442 enables the ribbon 430 to couple to the PV cell segment 425 without using a tab at the first end 404. More specifically, the PV cell segment 425 is coupled to the front electrode 446 and the ribbon is coupled to ribbon electrode 448. In the example embodiment, the rear electrode 444 of the first type connection cell 442 is not used when the first type connection cell 442 is connected to the last segment 425 at the first end 404 of the string. In at least some embodiments, the connector cell 442 does not include the rear electrode 444 or the front electrode 446. Alternatively, the rear electrode 444 or the front electrode 446 may be removed or otherwise insulated when not in use.

FIG. 9 is a cross-section of the middle portion 406 including the first type connection cell 442. The first type connection cell 442 is used to eliminate internal gaps between strings of the PV cell segments, such as gaps 40, 45 shown in FIGS. 1A and 1B. In the example embodiment, two opposing PV cell segments 425 are coupled to rear and front electrodes 444, 446, respectively. The internal ribbon 436 is coupled at the ribbon electrode 448 to electrically couple the PV cell segments 425 to each other and the internal ribbon 436.

With reference now to FIGS. 10 and 12, the second type connection cell 450 includes a rear electrode 452 and a ribbon electrode 454. The second type connection cell 450 is configured to couple to the front electrode 427 of a PV cell segment 425 at the second end 408 of the PV cell string 420 to allow electrical connection to be made on the rear side of the string 420. The rear electrode 452 includes a pair of spaced apart terminals 452A and 452B (as shown in FIG. 12) that couple to two corresponding terminals of the PV cell segment 425. The ribbon electrode 454 includes a single terminal 454A. Similar to the ribbon electrode 448 of the first type connection cell 442, the ribbon electrode 454 facilitates reducing a number of soldering points and a simplified wiring system for the PV module 400.

In the example embodiment, the second type connection cell 450 is not a functional PV cell. For example, the second type connection cell 450 may be fabricated from a laminated material.

With reference again to FIG. 7, the connection cells 440 are fabricated to have a similar appearance as the PV cell segments 425 on the front side (i.e., the side facing the sun) of the PV module 400. For example, if the PV cell segments 425 are black on the front side, the connection cells 440 may be fabricated to substantially match the color of the PV cell segments 425. In addition to substantially matching the color of the PV cell segments 425 and the connection cells 440, a backsheet (not shown) with the same or similar color may be placed behind the PV cell strings 420. When viewing the PV module 400 from the front side, the backsheet provides the same color as the PV cell strings 420 within gap 409 to cause the front surface of the PV module 400 to appear continuous.

Moreover, the connection cells 440 may have added details, such as fingers and busbars, printed, inlaid, or otherwise provided on the visible, front surface of the PV module 400. Although the PV module 400 is described with arrangement of the connector cells 440 shown in FIG. 7, it is to be understood that different configurations of connection cells may be used. For example, the PV module 400 may include different types, numbers and positions of connection cells.

The patches 460 extend between the adjacent PV cell strings 420 through the gap 409. More specifically, the patches 460 are positioned between the PV cell strings 420 and the ribbon 430. The patches 460 are configured to conceal the ribbon 430 from view through the gap 409 when viewed from the front of the PV module 400. In addition, the patches 460 may be configured to provide additional support to the PV cell strings and/or to insulate the ribbon from the front side 401 (shown in FIGS. 8-10) of the PV cell segments 425. In some embodiments, the patches 460 are made of a similar material as the backsheet. In other embodiments, the patches may be made of a different material, such as rubber.

In the example embodiment, the patches 460 are fabricated with a similar front side appearance as the PV cell segments 425, the connection cells 440, and the backsheet. By using patches 460 with a similar appearance, the PV module may appear to be continuous and visually appealing to at least some observers.

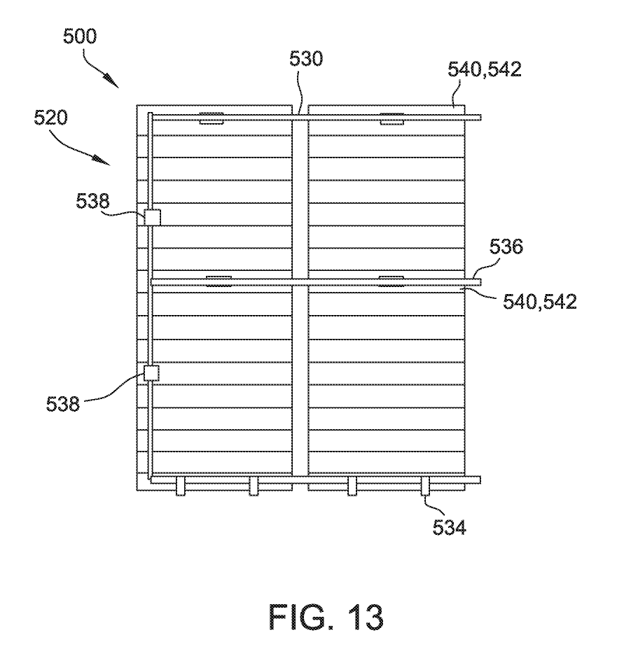

FIG. 13 is another example PV module 500 with shingled PV cell segments. The PV module 500 is similar to the PV module 400 shown in FIG. 7 and, in the absence of contrary representation, includes similar components and functionality. The PV module 500 includes a pair of PV cell strings 520, a conductive ribbon 530, and one or more connection cells 540.

The ribbon 530 includes a plurality of tabs 534, an intermediate ribbon 536, and bypass diodes 538. In the example embodiment, the tabs 534 are used in place of a second connection cell (e.g., second type connection cell 450, shown in FIG. 7). The connection cells 540 include first type connection cells 542 that are used to replace at least some tabs 534. In other embodiments, the tabs 534 may be used to replace one or more first type connection cells 542.

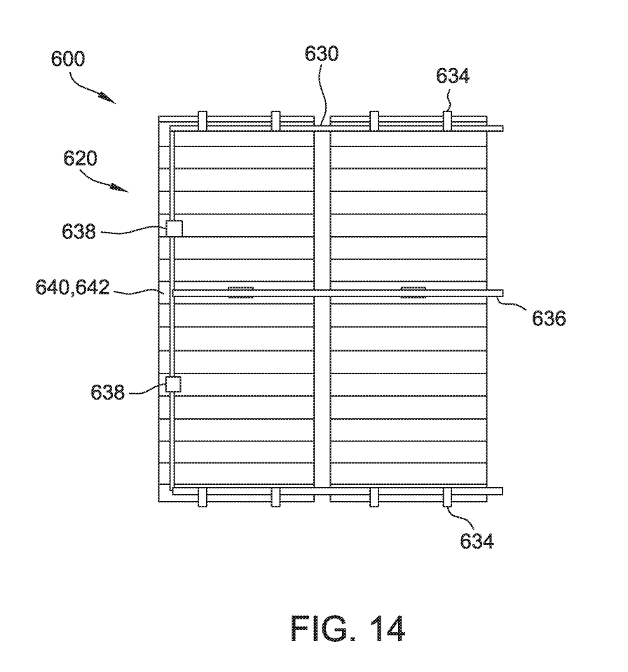

For example, FIG. 14 is another example PV module 600. The PV module 600 is similar to the PV modules 400, 500 shown in FIGS. 7 and 13 and, in the absence of contrary representation, includes similar components and functionality. The PV module 600 includes a pair of PV cell strings 620, a conductive ribbon 630, and one or more connection cells 640.

The ribbon 530 includes a plurality of tabs 634, an intermediate ribbon 636, and bypass diodes 638. In the example embodiment, the tabs 634 are used in place of first type connection cells 642 and second connection cells (e.g., second type connection cell 450, shown in FIG. 7) around a periphery of the PV module 600. The connection cells 640 include first type connection cells 642 that are used couple to the internal ribbon 636.

The techniques described herein may be used to produce PV modules with visually appealing aesthetics and simpler manufacturing. The electrical connection between shingled PV cell segments in strings of PV cell segments and a ribbon or busbar using connection cells facilitates positioning the ribbon behind the PV cell segments without extending to the front of the PV module. The PV modules of the present disclosure may be manufactured with a similar or continuous appearance from the front of the PV module, which may be visually appealing to users. In addition, the connection cells enable the process of coupling the ribbon to the PV cell strings to be simplified to single terminals on the PV cell segments.

When introducing elements of the present invention or the embodiment(s) thereof, the articles “a”, “an”, “the” and “said” are intended to mean that there are one or more of the elements. The terms “comprising”, “including” and “having” are intended to be inclusive and mean that there may be additional elements other than the listed elements.

Approximating language, as used herein throughout the specification and claims, may be applied to modify any quantitative representation that could permissibly vary without resulting in a change in the basic function to which it is related. Accordingly, a value modified by a term or terms, such as “about,” “approximately,” and “substantially,” is not to be limited to the precise value specified. In at least some instances, the approximating language may correspond to the precision of an instrument for measuring the value. Here and throughout the specification and claims, range limitations may be combined and/or interchanged; such ranges are identified and include all the sub-ranges contained therein unless context or language indicates otherwise.

As various changes could be made in the above without departing from the scope of the invention, it is intended that all matter contained in the above description and shown in the accompanying drawings shall be interpreted as illustrative and not in a limiting sense.

What is claimed is:

1. A shingled photovoltaic (PV) cell module comprising:
a first PV cell string comprising:
a plurality of shingled PV cell segments, each PV cell segment comprising a front electrode and an opposing rear electrode electrically coupled to the front electrode, wherein the front electrode of the PV cell segment is aligned and coupled with the rear electrode of an adjacent PV cell segment of the plurality of PV cell segments to electrically couple the plurality of PV cell segments in series; and
a first connection cell comprising a first electrode and a ribbon electrode electrically coupled to the first electrode, the first electrode electrically coupled to a first PV cell segment of the plurality of shingled PV cell segments, wherein the ribbon electrode is configured to be coupled to a conductor adjacent to the first PV cell string to transfer a power output of the plurality of PV cell segments.

2. The shingled PV cell module of claim 1, wherein the first connection cell further comprises a second electrode electrically coupled to the first electrode and the ribbon electrode.

3. The shingled PV cell module of claim 2, wherein the first electrode and the second electrode are positioned on opposite surfaces of the first connection cell.

4. The shingled PV cell module of claim 3, wherein the second electrode is electrically coupled to a second PV cell segment of the plurality of PV cell segments, wherein the first connection cell is disposed between the first PV cell segment and the second PV cell segment.

5. The shingled PV cell module of claim 1, wherein the first electrode and the ribbon electrode are positioned on the same surface of the first connection cell.

6. The shingled PV cell module of claim 5, wherein the first electrode and the ribbon electrode are positioned on a rear surface of the first connection cell, the first PV cell segment is located at an end of the first PV cell string with its rear electrode coupled to an adjacent PV cell segment, and the first electrode of the first connection cell is coupled to the front electrode of the first PV cell segment to allow the conductor to be coupled to the ribbon electrode on a rear side of the PV cell module.

7. The shingled PV cell module of claim 1 further comprising a second connection cell electrically coupled to the plurality of PV cells, the second connection cell including a first electrode and a ribbon electrode.

8. The shingled PV cell module of claim 7, wherein the first connection cell is coupled to the first PV cell segment at an end of the first PV cell string, the second connection cell is coupled between two adjacent PV cell segments in a middle portion of the first PV cell string.

9. The shingled PV cell module of claim 8 further comprising a third connection cell electrically coupled to the plurality of PV cells at an opposite end of the first PV cell string from the first connection cell.

10. The shingled PV cell module of claim 1 further comprising:
a second PV cell string spaced apart from the first PV cell string, the second PV cell string comprising:
a plurality of shingled PV cell segments; and
a second connection cell including a first electrode and a ribbon electrode electrically coupled to the first electrode, the first electrode electrically coupled to a first PV cell segment of the plurality of shingled PV cell segments; and
a conductor coupled to the ribbon electrodes of the first and second connection cells, the conductor extending across a gap between the first PV cell string and the second PV cell string.

11. The shingled PV cell module of claim 10 further comprising a patch disposed between the conductor and a portion of the first and second connection cells, the patch extending across the gap between the first PV cell string and the second PV cell string.

12. The shingled PV cell module of claim 11, wherein the plurality of shingled PV cell segments and the first connection cell have a front surface with a similar appearance.

13. The shingled PV cell module of claim 1, wherein the first connection cell is not a PV cell.

14. The shingled PV cell module of claim 1, wherein the first electrode comprises a pair of first electrode terminals and the ribbon electrode comprises a single ribbon electrode terminal electrically coupled to the pair of first electrode terminals.

15. A connection cell for coupling a shingled photovoltaic (PV) cell string comprising a plurality of PV cell segments to a conductor, the connection cell comprising:
a first electrode, the first electrode configured to be electrically coupled to a first PV cell segment of the plurality of PV cell segments; and
a ribbon electrode electrically coupled to the first electrode, the ribbon electrode configured to be coupled to a conductor adjacent to the PV cell string to transfer a power output of the plurality of PV cell segments.

16. The connection cell of claim 15, wherein the connection cell further comprises a second electrode electrically coupled to the first electrode and the ribbon electrode.

17. The connection cell of claim 16, wherein the first electrode and the second electrode are positioned on opposite surfaces of the connection cell.

18. The connection cell of claim 15, wherein the first and ribbon electrodes are positioned on the same surface of the connection cell.
